(19) United States
(12) Patent Application Publication
(10) Pub. No.: US 2018/0241408 A1
(43) Pub. Date: Aug. 23, 2018

(54) QUANTUM INTERFERENCE DEVICE, ATOMIC OSCILLATOR, AND ELECTRONIC APPARATUS

(71) Applicant: Seiko Epson Corporation, Tokyo (JP)

(72) Inventors: Nobuhito HAYASHI, Chino (JP); Yoshiyuki MAKI, Suwa (JP); Naoki ISHIHARA, Chino (JP); Takuya MIYAKAWA, Matsumoto (JP)

(21) Appl. No.: 15/901,369

(22) Filed: Feb. 21, 2018

(30) Foreign Application Priority Data
Feb. 23, 2017 (JP) 2017-032387

(51) Int. Cl. H03L 7/26; H01L 29/66; G01K 7/24

(52) U.S. Cl. CPC H03L 7/26; G01K 7/245; H01L 29/66977

(57) ABSTRACT

A quantum interference device includes an atomic cell which has an internal space enclosing an alkali metal, a first light source which emits a resonance light pair circularly polarized in the same direction as each other and exciting the alkali metal, a second light source which emits an adjustment light, and a light receiver, wherein the atomic cell includes a first layer which is provided on an inner wall surface surrounding the internal space of the atomic cell and contains a compound derived from a first compound that is an oxide of a metal having a lower ionization tendency than the alkali metal, a second layer which is provided on the first layer and contains a compound derived from a second compound having a functional group that undergoes an elimination reaction with the compound derived from the first compound, and a third layer which is provided on the second layer and contains a compound derived from a third compound that is nonpolar.

### CROSS-REFERENCE TO RELATED APPLICATIONS

This application claims priority to Japanese Patent Application No. 2017-032387, filed Feb. 23, 2017, the entirety of which is hereby incorporated by reference.

### BACKGROUND

### 1. Technical Field

The present invention relates to a quantum interference device, an atomic oscillator, and an electronic apparatus.

### 2. Related Art

As an oscillator having highly precise oscillation characteristics for a long period of time, there has been known an atomic oscillator utilizing a quantum interference effect (such as coherent population trapping (CPT)).

An atomic oscillator utilizing a quantum interference effect generally includes a gas cell which encloses an alkali metal in a gaseous state, a light source which emits a resonance light pair that resonates an alkali metal in the gas cell, and a light detector (light receiver) which detects the resonance light pair transmitting through the gas cell. In such an atomic oscillator, an electromagnetically induced transparency (EIT) signal generated accompanying an EIT phenomenon is detected by a light detector and used as a reference signal. Recently, for the purpose of improving the intensity of the EIT signal, an atomic oscillator using a circularly polarized resonance light pair has been developed. This can enhance short-term frequency stability.

By keeping the spin polarization of an alkali metal long, the interaction time between the light and the alkali metal can be increased, and as a result, the intensity of the EIT signal can be improved. However, the electron spin state (spin polarization) of the alkali metal is relaxed due to the collision with the inner wall of the gas cell. Therefore, in order to decrease the relaxation of the electron spin state due to the collision of the alkali metal with the inner wall, the pressure (partial pressure) of a buffer gas was increased in the related art. However, when increasing the pressure of the buffer gas, the relaxation of the electron spin state due to the collision of the alkali metal with the buffer gas was increased, and as a result, the interaction time was limited, and therefore, sufficient characteristics could not be obtained.

Therefore, recently, aside from the method for increasing the pressure of the buffer gas, for the purpose of decreasing the relaxation of the electron spin state due to the collision of an alkali metal with an inner wall of an atomic cell, a technique for coating the inner wall has been disclosed (JP-A-2013-181941). JP-A-2013-181941 discloses the use of a gas cell in which an OTS layer is formed on an inner wall of the gas cell so as to reduce the exposure of a polar group on the surface of the inner wall of the gas cell, and also a paraffin layer is formed on the OTS layer, whereby the non-relaxation property of the inner wall of the gas cell can be enhanced as an atomic oscillator.

However, in the atomic oscillator using a circularly polarized resonance light pair, when the interaction time is increased, a bias in the distribution of magnetic quantum number (a bias of the number of distribution of magnetic sublevels) occurs due to optical pumping by the resonance light pair which is a circularly polarized light, and the magnetic quantum number of an energy level actually causing an EIT phenomenon is decreased. As a result, the intensity of the EIT signal is decreased.

Further, in the gas cell described in JP-A-2013-181941, the alkali metal penetrates into the OTS layer (coating layer), and a bond between a molecule constituting the inner wall and a molecule constituting the coating layer is cleaved due to the alkali metal, and therefore, the coating layer is sometimes peeled off.

### SUMMARY

An advantage of some aspects of the invention is to provide a quantum interference device capable of reducing the possibility of peeling off of a coating and also capable of suppressing a decrease in the intensity of an EIT signal, and also to provide an atomic oscillator, an electronic apparatus, and a vehicle each including the quantum interference device.

The can be implemented as the following application examples or forms.

A quantum interference device according to an application example includes an atomic cell which has an internal space enclosing an alkali metal, a first light source which emits a resonance light pair that is circularly polarized in the same direction as each other and excites the alkali metal, a second light source which emits an adjustment light that is circularly polarized in an opposite direction to that of the resonance light pair and excites the alkali metal in the internal space, and a light receiver which receives the resonance light pair passing through the internal space, wherein the atomic cell includes a first layer which is provided on an inner wall surface surrounding the internal space of the atomic cell and contains a compound derived from a first compound that is an oxide of a metal having a lower ionization tendency than the alkali metal, a second layer which is provided on the first layer and contains a compound derived from a second compound having a functional group that undergoes an elimination reaction with the compound derived from the first compound, and a third layer which is provided on the second layer and contains a compound derived from a third compound that is nonpolar.

According to such a quantum interference device, by including the atomic cell having the first layer, the second layer, and the third layer, the relaxation of the electron spin state of the alkali metal is decreased or suppressed, so that the interaction time can be increased. Further, by including the second light source which emits the adjustment light in addition to the first light source which emits the resonance light pair, a bias in the distribution of the magnetic quantum number due to the increase in the interaction time can be reduced. Further, the first compound which is an oxide of a metal having a lower ionization tendency than the alkali metal does not undergo or hardly undergoes a substitution reaction with the alkali metal. Therefore, the cleavage of a bond between a compound of a material forming the inner wall surface and the first compound due to the alkali metal can be suppressed. Accordingly, the possibility of peeling off of the coating (the first layer, the second layer, and the third layer) can be reduced, and also the decrease in the intensity of the EIT signal can be suppressed.

In the quantum interference device according to the application example, it is preferred that the first compound is a tantalum oxide, a zirconium oxide, a hafnium oxide, or a titanium oxide.

By using such a first compound, the first compound does not undergo or hardly undergoes a substitution reaction with the alkali metal. Therefore, the possibility of peeling off of the coating can be reduced.

In the quantum interference device according to the application example, it is preferred that the second compound is an alkylsilane, an alcohol, or a polyimide.

According to this configuration, the orientation of the second layer can be enhanced, and further, the orientation of the third layer can also be enhanced. Therefore, the penetration of the alkali metal between the second compound molecules or between the third compound molecules can be suppressed. Accordingly, the relaxation of the electron spin state of the alkali metal can be particularly decreased.

In the quantum interference device according to the application example, it is preferred that the third compound is an olefin-based polymer.

According to this configuration, as compared with the paraffin coating in the related art, the heat resistance can be enhanced.

In the quantum interference device according to the application example, it is preferred that the third compound is polypropylene, polyethylene, or polymethylpentene.

According to this configuration, as compared with the paraffin coating in the related art, the melting point of the third layer can be increased, and thus, the heat resistance of the atomic cell can be enhanced as compared with the related art.

In the quantum interference device according to the application example, it is preferred that the first compound is a tantalum oxide, the second compound is octadecyltrimethoxysilane, and the third compound is polypropylene.

According to this configuration, the heat resistance of the atomic cell can be particularly enhanced, and also the relaxation of the electron spin state of the alkali metal can be particularly decreased. Further, the possibility of peeling off of the coating is particularly low, and the durability is high. Further, for example, as compared with a case where the second compound is OTS and the third compound is polyethylene, handling is easy, and higher heat resistance can be imparted.

An atomic oscillator according to an application example includes the quantum interference device according to the above application example.

According to this configuration, an atomic oscillator including the quantum interference device capable of reducing the possibility of peeling off of the coating and also capable of suppressing the decrease in the intensity of the EIT signal can be provided.

An electronic apparatus according to an application example includes the quantum interference device according to the above application example.

According to this configuration, by including the quantum interference device capable of reducing the possibility of peeling off of the coating and also capable of suppressing the decrease in the intensity of the EIT signal, an electronic apparatus having high characteristics can be provided.

A vehicle according to an application example includes the quantum interference device according to the above application example.

According to this configuration, by including the quantum interference device capable of reducing the possibility of peeling off of the coating and also capable of suppressing the decrease in the intensity of the EIT signal, a vehicle having high characteristics can be provided.

### BRIEF DESCRIPTION OF THE DRAWINGS

The embodiments will be described with reference to the accompanying drawings, wherein like numbers reference like elements.

FIG. 1 is a schematic view showing an example of an atomic oscillator (quantum interference device) according to an embodiment.

FIG. 2 is a schematic view for illustrating a light source unit included in the atomic oscillator.

FIG. 3 is a view for illustrating a light emitted from each of a first light source and a second light source of the light source unit.

FIG. 4 is a vertical cross-sectional view of the atomic cell shown in FIG. 2.

FIG. 5 is a transverse cross-sectional view of the atomic cell shown in FIG. 2.

FIG. 6 is a view showing one example of a relationship between the energy state of a cesium atom and a resonance light pair (a first resonance light and a second resonance light) and an adjustment light (a third resonance light).

FIGS. 7A and 7B are views showing the distribution of the magnetic quantum number of a sodium atom, and FIG. 7A is a view showing the distribution when the sodium atom was irradiated with a resonance light which is a σ⁺-circularly polarized light, and FIG. 7B is a view showing the distribution when the sodium atom was irradiated with a resonance light which is a σ⁻-circularly polarized light.

FIG. 8 is a schematic view showing an inner wall surface and a coating of the atomic cell.

FIG. 9 is a view for illustrating one example of a polar group of the inner wall surface before forming the coating.

FIG. 10 is a view for illustrating one example of the structure of a second layer.

FIG. 11 is a view for illustrating one example of the structure of the coating.

FIG. 12 is a graph showing a relationship between a buffer gas enclosed in an internal space of the atomic cell and a relaxation rate.

FIG. 13 is a flowchart illustrating a production method for the atomic cell.

FIG. 14 is a view illustrating a vessel preparation step shown in FIG. 13.

FIG. 15 is a view illustrating a third layer forming step shown in FIG. 13.

FIG. 16 is a view showing a schematic structure in a case where an atomic oscillator according to an embodiment is used in a positioning system utilizing a global positioning system (GPS) satellite as an example of a positioning satellite.

FIG. 17 is a view showing one example of a vehicle according to an embodiment.

### DESCRIPTION OF EXEMPLARY EMBODIMENTS

Hereinafter, embodiments of a quantum interference device, an atomic oscillator, an electronic apparatus, and a vehicle will be described in detail with reference to the accompanying drawings.

### 1. Atomic Oscillator (Quantum Interference Device)

First, an atomic oscillator according to this embodiment will be described. Hereinafter, an example in which a quantum interference device according to the embodiment is applied to an atomic oscillator will be described, however, the quantum interference device according to the embodiment is not limited thereto, and can also be applied to, for example, devices such as a magnetic sensor and a quantum memory.

First, the atomic oscillator according to the embodiment will be briefly described.

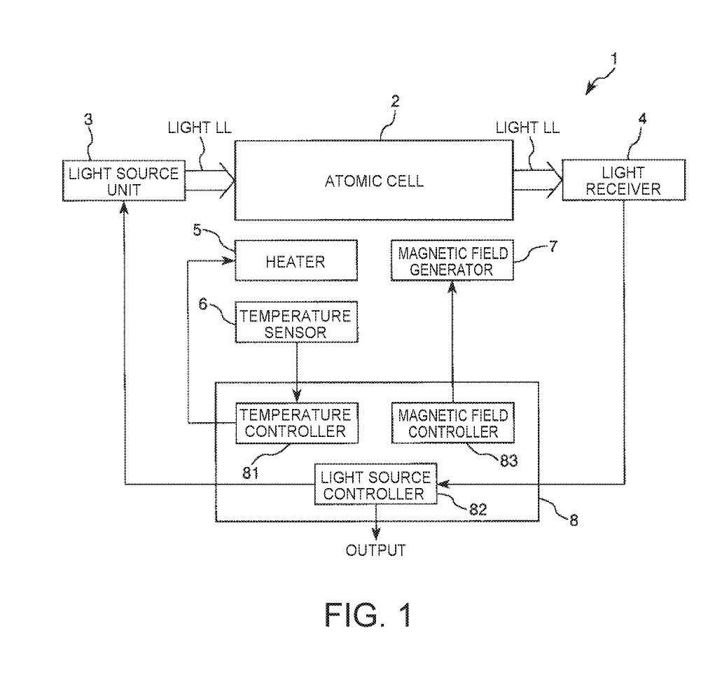

FIG. 1 is a schematic view showing an example of the atomic oscillator (quantum interference device) according to the embodiment.

An atomic oscillator 1 shown in FIG. 1 is an atomic oscillator utilizing a quantum interference effect. As shown in FIG. 1, the atomic oscillator 1 includes an atomic cell (gas cell) 2, a light source unit 3, a light receiver 4, a heater 5, a temperature sensor 6, a magnetic field generator 7, and a controller 8.

First, the principle of the atomic oscillator 1 will be briefly described.

As shown in FIG. 1, in the atomic oscillator 1, the light source unit 3 emits a light LL toward the atomic cell 2, and the light receiver 4 detects the light LL transmitting through the atomic cell 2.

In the atomic cell 2, an alkali metal in a gaseous state is enclosed. The alkali metal has energy levels of a three-level system including two ground levels (a first ground level and a second ground level) and an excited level. Here, the first ground level is an energy state lower than the second ground level.

The light LL emitted from the light source unit 3 includes a first resonance light and a second resonance light as two types of resonance lights having different frequencies. When irradiating the alkali metal in a gaseous state as described above with the first resonance light and the second resonance light, the light absorption ratios (light transmittances) of the first resonance light and the second resonance light in the alkali metal change according to a difference (ω₁−ω₂) between the frequency ω₁ of the first resonance light and the frequency ω₂ of the second resonance light.

When the difference (ω₁−ω₂) between the frequency ω₁ of the first resonance light and the frequency ω₂ of the second resonance light coincides with a frequency corresponding to the energy difference ΔE between the first ground level and the second ground level, excitation from the first ground level and the second ground level to the excited level stops, respectively. At this time, the first resonance light and the second resonance light both transmit through the alkali metal without being absorbed. Such a phenomenon is called a CPT phenomenon or an electromagnetically induced transparency (EIT) phenomenon.

For example, in a case where the frequency ω₁ of the first resonance light is fixed and the frequency ω₂ of the second resonance light is changed, the detection intensity of the light receiver 4 steeply increases when the difference (ω₁−ω₂) between the frequency ω₁ of the first resonance light and the frequency ω₂ of the second resonance light coincides with a frequency ω₀ corresponding to the energy difference ΔE between the first ground level and the second ground level. Such a steep signal is detected as an EIT signal. The EIT signal has an eigenvalue determined according to the type of alkali metal. Accordingly, an oscillator with high precision can be formed by using such an EIT signal as a reference.

Hereinafter, the respective sections of the atomic oscillator 1 will be briefly described.

### Atomic Cell

In the atomic cell 2, an alkali metal such as rubidium, cesium, or sodium in a gaseous state is enclosed. In the atomic cell 2, a rare gas such as argon or neon or an inert gas such as nitrogen may be enclosed as a buffer gas along with the alkali metal gas as needed.

As will be described in detail later, the atomic cell 2 has a body part having a through hole, and a pair of window parts closing the opening of the through hole of the body part, and therefore, an internal space enclosing the alkali metal in a gaseous state is formed.

### Light Source Unit

The light source unit 3 has a function of emitting the light LL including the first resonance light and the second resonance light described above constituting the resonance light pair for resonating the atoms of the alkali metal (alkali metal atoms) in the atomic cell 2.

The light LL emitted by the light source unit 3 includes a third resonance light in addition to the first resonance light and the second resonance light.

The first resonance light is a light (probe light) for exciting the alkali metal atoms in the atomic cell 2 from the first ground level described above to the excited level. On the other hand, the second resonance light is a light (coupling light) for exciting the alkali metal atoms in the atomic cell 2 from the second ground level described above to the excited level. Here, the first resonance light and the second resonance light are circularly polarized in the same direction as each other. Further, the third resonance light is an “adjustment light” (repump light) for adjusting the magnetic quantum number of the alkali metal atom in the atomic cell 2. The third resonance light is circularly polarized in an opposite direction to that of the first resonance light and the second resonance light. Accordingly, the magnetic quantum number of the alkali metal atom in the atomic cell 2 can be adjusted. The light source unit 3 will be described in detail later. The “circularly polarized light” refers to a light, in which the vibration direction rotates at the frequency of the light wave in a plane perpendicular to the traveling direction of the light when focusing on the vibration of either one of the electric field component and the magnetic field component of the light wave, and the amplitude of the vibration is constant regardless of the direction, and in other words, a light in which the vibration of the electric field (or the magnetic field) draws a circle with the propagation.

### Light Receiver

The light receiver 4 has a function of detecting the intensity of the light LL (particularly, the resonance light pair constituted by the first resonance light and the second resonance light) transmitting through the atomic cell 2.

The light receiver 4 is not particularly limited as long as it can detect the intensity of the light LL as described above, however, for example, a light detector (light receiving element) such as a photodiode which outputs a signal according to the intensity of the received light can be used.

### Heater

The heater 5 (heating section) has a function of heating the atomic cell 2 (more specifically, the alkali metal in the atomic cell 2) described above. According to this, the alkali metal in the atomic cell 2 can be maintained in a gaseous state at an appropriate concentration.

The heater 5 is configured to include, for example, a heating resistor which generates heat by applying an electric current thereto. The heating resistor may be provided in contact with the atomic cell 2 or may be provided in non-contact with the atomic cell 2.

More specifically, in a case where the heating resistor is provided in contact with the atomic cell 2, the heating resistor is provided for each of the pair of window parts of the atomic cell 2. According to this, it is possible to prevent the alkali metal from condensing on the window parts of the atomic cell 2. As a result, the characteristics (oscillation characteristics) of the atomic oscillator 1 can be made excellent for a long period of time. Such a heating resistor is constituted by a material having transmittance for the light LL, specifically, a transparent electrode material such as an oxide, for example, ITO (indium tin oxide), IZO (indium zinc oxide), In₃O₃, SnO₂, Sb-doped SnO₂, Al-doped ZnO, or the like. Further, such a heating resistor can be formed using, for example, chemical vapor deposition (CVD) such as plasma CVD or thermal CVD, a dry plating method such as vacuum deposition, a sol-gel method, or the like.

In a case where the heating resistor is provided in non-contact with the atomic cell 2, heat may be conducted from the heating resistor to the atomic cell 2 through a metal or the like having excellent heat conductivity or a member such as a ceramic.

The heater 5 is not limited to the above-mentioned configuration as long as the atomic cell 2 can be heated, and various types of heaters can be used. Further, the temperature of the atomic cell 2 may be adjusted using a Peltier element in place of or in combination with the heater 5.

### Temperature Sensor

The temperature sensor 6 has a function of detecting the temperature of the heater 5 or the atomic cell 2.

The temperature sensor 6 is placed, for example, in contact with the heater 5 or the atomic cell 2.

The temperature sensor 6 is not particularly limited, and various types of known temperature sensors such as a thermistor and a thermocouple can be used.

### Magnetic Field Generator

The magnetic field generator 7 has a function of applying a magnetic field to the alkali metal located in the atomic cell 2. According to this, it is possible to improve the resolution by enlarging gaps between a plurality of different energy levels that degenerate the alkali metal atoms in the atomic cell 2 by Zeeman splitting. As a result, the precision of the oscillation frequency of the atomic oscillator 1 can be improved.

The magnetic field generator 7 may be constituted by, for example, a coil which is provided and wound along the periphery of the atomic cell 2 so as to constitute a solenoid type, or may be constituted by a pair of coils which are provided facing each other through the atomic cell 2 so as to constitute a Helmholtz type.

The magnetic field generated by the magnetic field generator 7 is a constant magnetic field (direct current magnetic field), however, alternating current magnetic fields may be superimposed.

### Controller

The controller 8 has a function of controlling each of the light source unit 3, the heater 5, and the magnetic field generator 7.

The controller 8 includes a light source controller 82 which controls the light source unit 3, a temperature controller 81 which controls the temperature of the alkali metal in the atomic cell 2, and a magnetic field controller 83 which controls the magnetic field from the magnetic field generator 7.

The light source controller 82 has a function of controlling the frequencies of the first resonance light and the second resonance light emitted from the light source unit 3 based on the detection result of the light receiver 4. More specifically, the light source controller 82 controls the frequencies of the first resonance light and the second resonance light emitted from the light source unit 3 such that the above-mentioned frequency difference (ω₁−ω₂) becomes the above-mentioned frequency ω₀ specific to the alkali metal. The configuration of the light source controller 82 will be described in detail later.

The temperature controller 81 controls the application of an electric current to the heater 5 based on the detection result of the temperature sensor 6. According to this, it is possible to maintain the atomic cell 2 within a desired temperature range. For example, the temperature of the atomic cell 2 is adjusted to, for example, about 70° C. by the heater 5.

The magnetic field controller 83 controls the application of an electric current to the magnetic field generator 7 such that the magnetic field generated by the magnetic field generator 7 is constant.

Such a controller 8 is configured to include, for example, a central processing device, a memory, an interface circuit, an oscillator, etc.

Hereinabove, the configuration of the atomic oscillator 1 has been briefly described.

### Detailed Description of Light Source Unit

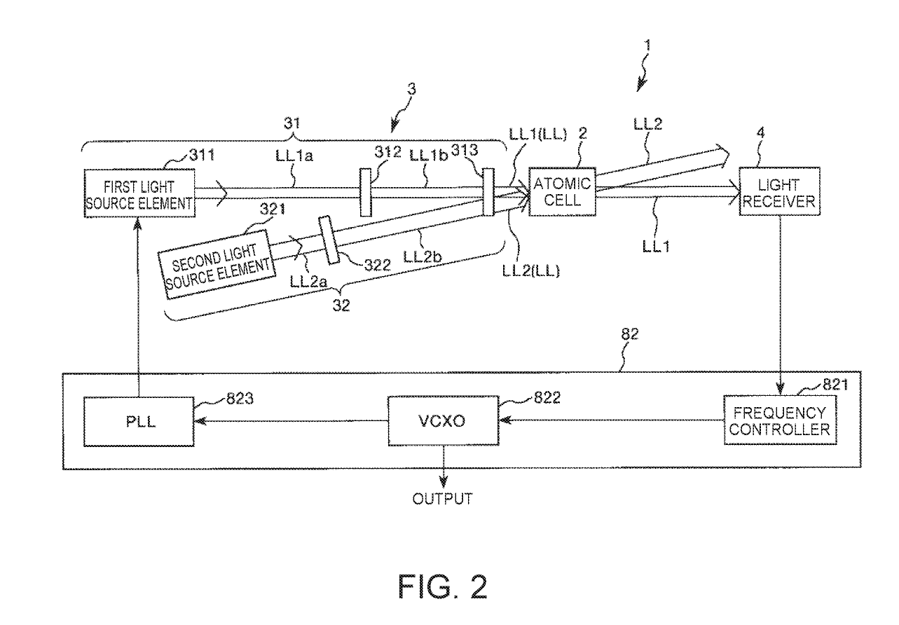

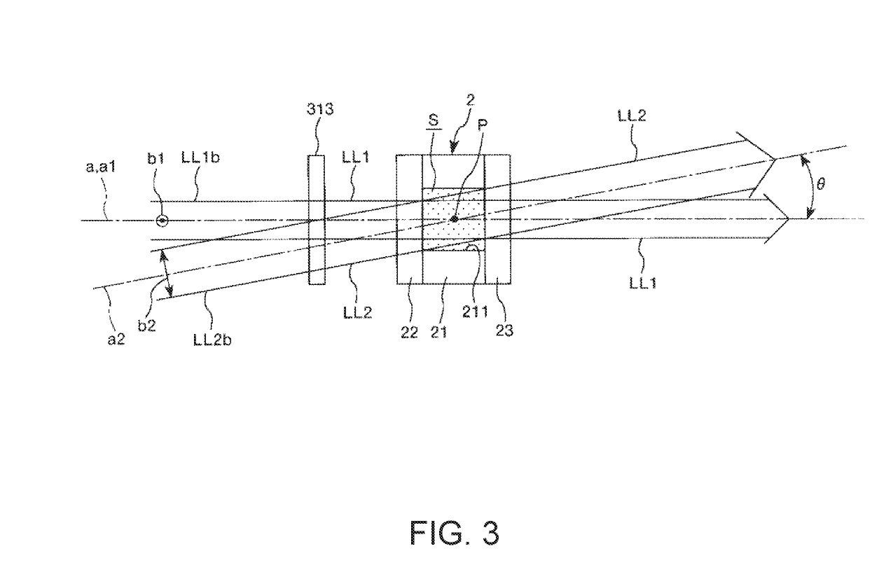

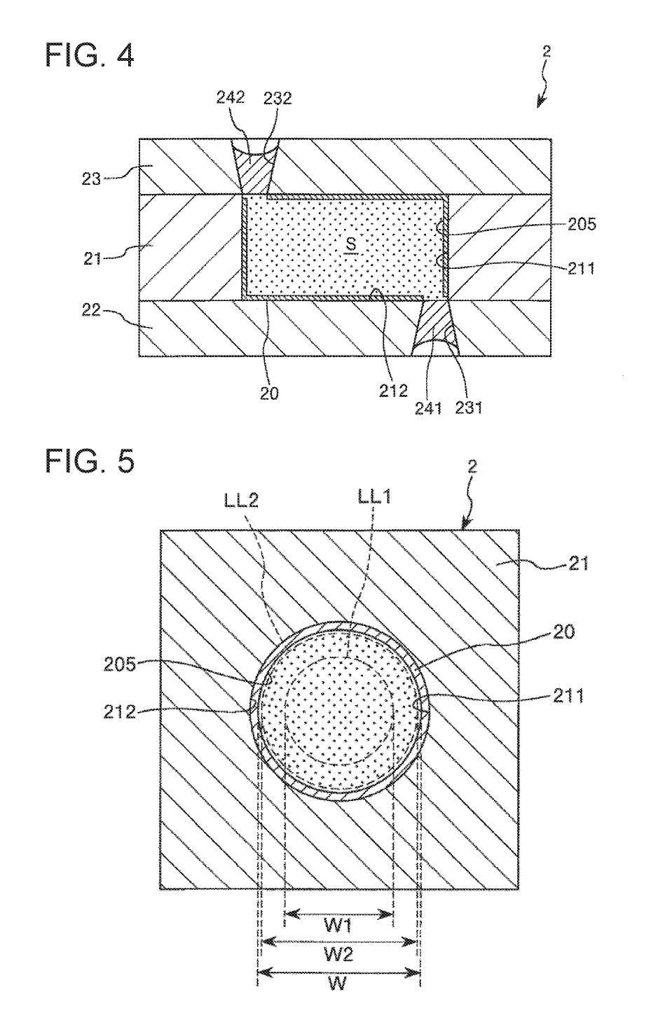

FIG. 2 is a schematic view for illustrating the light source unit included in the atomic oscillator. FIG. 3 is a view for illustrating a light emitted from each of a first light source and a second light source of the light source unit. FIG. 4 is a vertical cross-sectional view of the atomic cell shown in FIG. 2, that is, a cross-sectional view parallel to the window parts. FIG. 5 is a transverse cross-sectional view of the atomic cell shown in FIG. 2, that is, a cross-sectional view perpendicular to a direction in which the pair of window parts is arranged.

As shown in FIG. 2, the light source unit 3 includes a first light source 31 which emits a resonance light pair LL1 including the first resonance light and the second resonance light as a first light and a second light source 32 which emits an adjustment light LL2 including the third resonance light as a second light.

The first light source 31 includes a first light source element 311, a ½ wavelength plate 312, and a ¼ wavelength plate 313.

The first light source element 311 has a function of emitting a first light LL1a composed of a linearly polarized resonance light pair. The first light source element 311 is not particularly limited as long as it can emit a light including the first light LL1a, but is, for example, a semiconductor laser such as an edge emitting laser or a vertical cavity surface emitting laser (VCSEL). The “linearly polarized light” is a light in which the vibrating surfaces of electromagnetic waves (lights) are included in the same plane, in other words, a light in which the vibration direction of the electric field (or the magnetic field) is constant.

The ½ wavelength plate 312 is a birefringent element which produces a phase difference π (180°) between the polarized light components which are orthogonal to each other. Accordingly, the ½ wavelength plate 312 generates a resonance light pair LL1b by changing the polarization direction of the first light LL1a which is a linearly polarized light from the first light source element 311 by 90°. In a case where the first light source element 311 is installed in a posture which is rotated by 90° around the optical axis, the linearly polarized light emitted from the first light source element 311 is orthogonal to the polarization direction of the linearly polarized light emitted from the below-mentioned second light source element 321. Therefore, the ½ wavelength plate 312 can be omitted.

The ¼ wavelength plate 313 is a birefringent element which produces a phase difference of π/2 (90°) between the polarized light components which are orthogonal to each other. The ¼ wavelength plate 313 has a function of converting the resonance light pair LL1b generated by the ½ wavelength plate 312 from the linearly polarized light into the resonance light pair LL1 which is a circularly polarized light (including an elliptically polarized light). According to this, it is possible to generate the resonance light pair LL1 constituted by the first resonance light and the second resonance light described above.

On the other hand, the second light source 32 includes a second light source element 321, a dimming filter 322, and the above-mentioned ¼ wavelength plate 313 which is common to the first light source 31. Here, the ¼ wavelength plate 313 can be said to be included in the first light source 31 as described above and can also be said to be included in the second light source 32.

The second light source element 321 has a function of emitting a second light LL2a composed of a resonance light which is linearly polarized in the same direction as the above-mentioned first light source element 311. The second light source element 321 is not particularly limited as long as it can emit a light including the second light LL2a, but is, for example, a semiconductor laser such as an edge emitting laser or a VCSEL, or a light emitting element such as a light emitting diode (LED) or an organic electroluminescence element.

The dimming filter 322 is, for example, a neutral density (ND) filter and generates a resonance light LL2b by decreasing the intensity of the second light LL2a from the second light source element 321. Due to this, even if the output of the second light source element 321 is large, the quantity of the adjustment light LL2 to be incident on the atomic cell 2 can be decreased to a desired level. When the output of the second light source element 321 is less than that of the first light source element 311 or the like, the dimming filter 322 can be omitted.

As described above, the ¼ wavelength plate 313 is a birefringent element which produces the phase difference π/2 (90°) between the polarized light components which are orthogonal to each other. The ¼ wavelength plate 313 has a function of converting the resonance light LL2b generated by the dimming filter 322 from the linearly polarized light into the adjustment light LL2 which is a circularly polarized light (including an elliptically polarized light). According to this, it is possible to generate the adjustment light LL2 constituted by the third resonance light described above. Here, the polarization direction (a direction b2 shown in FIG. 3) of the linearly polarized resonance light LL2b is a direction (orthogonal direction) which is different from the polarization direction (a direction b1 shown in FIG. 3) of the linearly polarized resonance light pair LL1b. Accordingly, by allowing the resonance light pair LL1b and the resonance light LL2b to pass through the common ¼ wavelength plate 313, the circularly polarized resonance light pair LL1 and the adjustment light LL2 which is circularly polarized in the opposite direction to that of the resonance light pair LL1 can be generated. In this manner, the first light source 31 and the second light source 32 include the common ¼ wavelength plate 313 through which both the resonance light pair LL1 and the adjustment light LL2 pass, and therefore, as compared with a case where each of the first light source 31 and the second light source 32 includes a ¼ wavelength plate individually, the configuration of the device can be simplified.

The light source unit 3 configured as described above is controlled by the light source controller 82 such that the first light source element 311 emits the first resonance light and the second resonance light.

### Detailed Description of Light Source Controller

The light source controller 82 includes a frequency controller 821, a voltage controlled oscillator (VCO) 822, and a phase locked loop (PLL) circuit 823.

The frequency controller 821 detects an EIT state in the atomic cell 2 based on the intensity of the light received by the light receiver 4, and outputs a control voltage according to the result of the detection. Therefore, the frequency controller 821 controls the voltage controlled oscillator 822 such that an EIT signal is detected by the light receiver 4.

The voltage controlled oscillator 822 is controlled by the frequency controller 821 such that the oscillation frequency becomes a desired level, and oscillates at a frequency of, for example, about several MHz to several tens of MHz. The output signal from the voltage controlled oscillator 822 is input to the phase locked loop circuit 823 and is output as the output signal of the atomic oscillator 1.

The phase locked loop circuit 823 multiplies the frequency of the output signal from the voltage controlled oscillator 822. By doing this, the phase locked loop circuit 823 oscillates at a frequency which is half the frequency corresponding to the energy difference ΔE between the above-mentioned two different ground levels of the alkali metal atoms. The thus multiplied signal (high frequency signal) is input to the first light source element 311 of the first light source 31 as a driving signal after DC bias currents are superimposed. By doing this, the light emitting element such as the semiconductor laser included in the first light source element 311 is modulated, and thus, the first resonance light and the second resonance light as two lights in which the frequency difference (ω₁−ω₂) becomes ω₀ can be emitted. Here, the current value of the DC bias current is controlled to be a predetermined value by a bias controller (not shown). According to this, it is possible to control the central wavelength of the first resonance light and the second resonance light to a desired level.

The temperature of each of the first light source element 311 and the second light source element 321 is adjusted to a predetermined temperature by a temperature adjustment element (such as a heating resistor or a Peltier element) (not shown). Further, by adjusting the temperatures of the first light source element 311 and the second light source element 321, the central wavelengths of lights emitted from the first light source element 311 and the second light source element 321 can also be controlled.

The atomic cell 2 is irradiated with the resonance light pair LL1 and the adjustment light LL2 emitted from the first light source 31 and the second light source 32 constituted as described above.

### Detailed Description of Atomic Cell

As shown in FIG. 4, the atomic cell 2 includes a body part 21 and a pair of window parts 22 and 23 provided interposing the body part 21 therebetween. In the atomic cell 2, the body part 21 is placed between the pair of window parts 22 and 23, and the body part 21 and the pair of window parts 22 and 23 define and form (constitute) the internal space S enclosing the alkali metal in a gaseous state. Further, the surface facing the internal space S, that is, the inner wall surface 212 of the body part 21 and the window parts 22 and 23 is provided with a coating 20.

The body part 21 has a plate shape, and in the body part 21, a through hole 211 passing therethrough in the thickness direction of the body part 21 is formed.

The constituent material of the body part 21 is not particularly limited and includes a glass material, a quartz crystal, a metal material, a resin material, a silicon material, and the like. Above all, it is preferred to use any of a glass material, a quartz crystal, and a silicon material. According to this, even if a small atomic cell 2 having a width and a height of 10 mm or less is formed, the body part 21 with high precision can be easily formed using a microfabrication technique such as etching.

The window part 22 is bonded to one surface of the body part 21, and the window part 23 is bonded to the other surface of the body part 21. According to this, the opening at one end of the through hole 211 is closed by the window part 22, and also the opening at the other end of the through hole 211 is closed by the window part 23.

A method for bonding the body part 21 to the window parts 22 and 23 is determined according to the constituent material of these members and is not particularly limited as long as airtight bonding can be performed, and for example, a bonding method using an adhesive, a direct bonding method, an anodic bonding method, a surface activation bonding method, or the like can be used.

Each of the window parts 22 and 23 to be bonded to the body part 21 has transmittance for the light LL from the light source unit 3. The window part 22 which is one of the window parts is an incident side window part through which the light LL is incident into the internal space S of the atomic cell 2, and the window part 23 which is the other window part is an emission side window part through which the light LL is emitted from the internal space S of the atomic cell 2. Each of the window parts 22 and 23 has a plate shape.

The constituent material of the window parts 22 and 23 is not particularly limited as long as the material has transmittance for the light LL as described above, and includes, for example, a glass material, a quartz crystal, and the like, however, it is preferred to use a glass material. According to this, it is possible to realize the window parts 22 and 23 having transmittance for the excited light.

The alkali metal in a gaseous state is mainly stored in the internal space S which is a space in the through hole 211 closed by the window parts 22 and 23. The alkali metal in a gaseous state stored in the internal space S is excited by the light LL. Here, at least a part of the internal space S forms a “light passage space” through which the light LL passes. In this embodiment, the transverse cross section of the internal space S has a circular shape, and the transverse cross section of the light passage space has a similar shape (that is, a circular shape) to the transverse cross section of the internal space S and is set substantially equal to or slightly smaller than the transverse cross section of the internal space S. The transverse cross-sectional shape of the internal space S is not limited to a circle, and may be, for example, a polygon such as a rectangle or a pentagon, an ellipse, or the like.

In the window part 22, a through hole 231 passing through a region between the internal space S and the outside is formed, and the through hole 231 is sealed by a sealant 241. Similarly, in the window part 23, a through hole 232 passing through a region between the internal space S and the outside is formed, and the through hole 232 is sealed by a sealant 242.

As the constituent material of the sealants 241 and 242 is not particularly limited as long as the material can airtightly seal the through holes 231 and 232, and for example, a metal material, a glass material, or the like can be used, but it is preferred to use a glass material. According to this, it is possible to airtightly close the through holes 231 and 232 easily and reliably. Further, the effect of the sealants 241 and 242 on the chemical properties of the alkali metal can be reduced.

As will be described in detail later, the through holes 231 and 232 are used for introducing a coating material (the first compound, the second compound, and the third compound) for forming the below-mentioned coating 20 into the internal space S or the like when producing the atomic cell 2. In this embodiment, each of the through holes 231 and 232 has a truncated conical shape, however, the through holes 231 and 232 are not limited thereto.

On the inner wall surface 212 of the body part 21 and the window parts 22 and 23, the coating 20 is provided. The coating 20 has a function of decreasing or suppressing the relaxation of the electron spin state (spin polarization) of the alkali metal due to the collision thereof with the inner wall 212.

It is only necessary that the coating 20 be provided on at least a part of the inner wall surface 212, however, the coating 20 is preferably provided on at least the surfaces of the inner walls of the window parts 22 and 23, more preferably on the entire inner wall surface 212 as shown in FIG. 4. Further, although not shown in the drawing, the coating 20 may be provided also on the entire inner walls forming the through holes 231 and 232 or on a portion close to the internal space S. The coating 20 will be described in detail later.

In the atomic cell 2 configured as described above, as shown in FIG. 3, the optical axis a1 of the resonance light pair LL1 is inclined at an inclination angle θ with respect to the optical axis a2 of the adjustment light LL2 and intersects the optical axis a2 at an intersection point P. In FIG. 3, in the atomic cell 2, the optical axis a1 of the resonance light pair LL1 is parallel to an axial line a along a direction in which the window part 22 and the window part 23 of the atomic cell 2 are arranged. On the other hand, the optical axis a2 of the adjustment light LL2 is inclined at an inclination angle θ with respect to the axial line a. In FIG. 3, the optical axis a1 coincides with the axial line a.

Here, on the side where the resonance light pair LL1 and the adjustment light LL2 are emitted of the atomic cell 2, the light receiver 4 is placed on the optical axis a1 or the extension line thereof, and the resonance light pair LL1 passing through the atomic cell 2 is received by the light receiver 4. On the other hand, the optical axis a2 is placed such that the light receiver 4 does not receive the adjustment light LL2 passing through the atomic cell 2. According to this, it is possible to prevent or reduce the reception of the adjustment light LL2 by the light receiver 4.

In this embodiment, the adjustment light LL2 passing through the atomic cell 2 is incident on a reflection prevention part (not shown) so as not to be a stray light. The adjustment light LL2 passing through the atomic cell 2 may be received by the light receiving element, and the second light source 32 may be controlled according to the detection result of the light receiving element.

Further, as shown in FIG. 5, in the atomic cell 2, the width W2 of the adjustment light LL2 is larger than the width W1 of the resonance light pair LL1. Therefore, in the atomic cell 2, the passing region of the resonance light pair LL1 is included in the passing region of the adjustment light LL2.

The width W2 of the adjustment light LL2 may be equal to the width W in the atomic cell 2.

### Relationship Between Energy State of Alkali Metal Atom and Resonance Light Pair and Adjustment Light

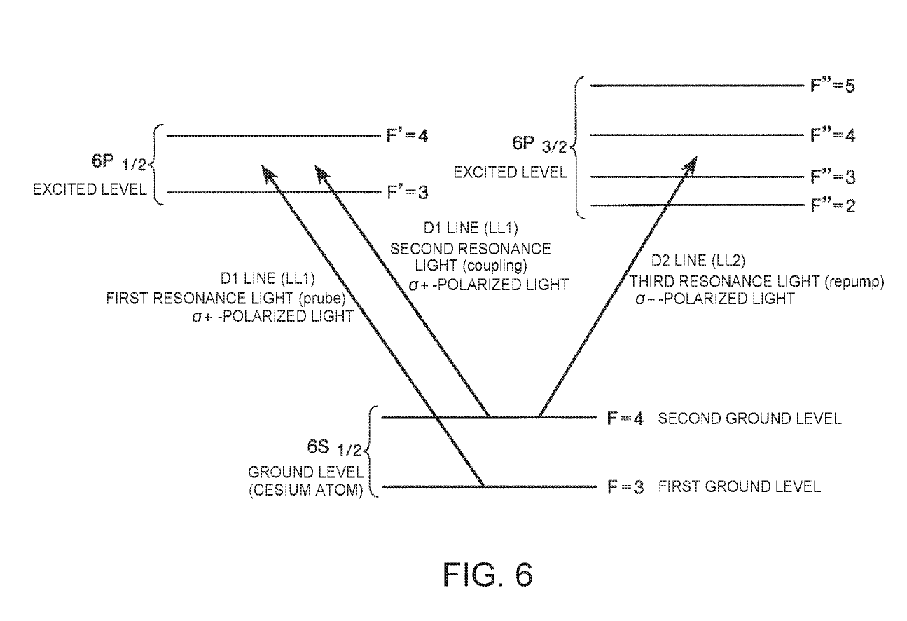

FIG. 6 is a view showing one example of a relationship between the energy state of a cesium atom and the resonance light pair (the first resonance light and the second resonance light) and the adjustment light (the third resonance light).

For example, in a case where the atomic cell 2 encloses cesium atoms, as shown in FIG. 6, a σ⁺-polarized (left-handed circularly polarized) D1 line is used as the first resonance light and the second resonance light (resonance light pair) and a σ⁻-polarized (right-handed circularly polarized) D2 line is used as the third resonance light (adjustment light). The first resonance light and the second resonance light may each be a σ⁻-polarized light and the third resonance light may be a σ⁺-polarized light. In addition, the first resonance light and the second resonance light may be the D2 line, and the third resonance light may be the D1 line.

The cesium atom which is one type of alkali metal atom has the ground level of 6S_{1/2} and the two excited levels of 6P_{1/2} and 6P_{3/2}. Further, each of the levels of 6S_{1/2}, 6P_{1/2}, and 6P_{3/2} has a microstructure that is split into a plurality of energy levels. More specifically, the level of 6S_{1/2} has two ground levels of F=3 and 4, the level of 6P_{1/2} has two excited levels of F′=3 and 4, and the level of 6P_{3/2} has four excited levels of F″=2, 3, 4, and 5.

The cesium atom in the first ground level of F=3 in 6S_{1/2} can make the transition to the excited level of any of F″=2, 3, and 4 in 6P_{3/2} by absorbing the D2 line, but cannot make the transition to the excited level of F″=5. The cesium atom in the second ground level of F=4 in 6S_{1/2} can make the transition to the excited level of any of F″=3, 4, and 5 in 6P_{3/2} by absorbing the D2 line, but cannot make the transition to the excited level of F″=2. These are derived from the transition selection rule in a case of assuming the electric dipole transition. On the contrary, the cesium atom in the excited level of either of F″=3 and 4 in 6P_{3/2} can make the transition to the ground level (either the original ground level or the other ground level) of F=3 or F=4 in 6S_{1/2} by releasing the D2 line. Three levels including the two ground levels of F=3 and 4 in 6S_{1/2} and the excited level of either of F″=3 and 4 in 6P_{3/2} described above are called Λ-type three levels since Λ-type transition due to absorption/emission of the D2 line can be made. Similarly, three levels including the two ground levels of F=3 and 4 in 6S_{1/2} and the excited level of either of F′=3 and 4 in 6P_{1/2} also form the Λ-type three levels since the Λ-type transition due to absorption/emission of the D1 line can be made.

On the other hand, the cesium atom in the excited level of F″=2 in 6P_{3/2} releases the D2 line to inevitably make the transition to the ground level (the original ground level) of F=3 in 6S_{1/2}, and in a similar manner, the cesium atom in the excited level of F″=5 in 6P_{3/2} releases the D2 line to inevitably make the transition to the ground level (the original ground level) of F=4 in 6S_{1/2}. Therefore, the three levels including the two ground levels of F=3 and 4 in 6S_{1/2} and the excited level of F=2 or F=5 in 6P_{3/2} do not form the Λ-type three levels since the Λ-type transition due to absorption/emission of the D2 line cannot be made.

In such a cesium atom, the wavelength of the D1 line in vacuum is 894.593 nm, the wavelength of the D2 line in vacuum is 892.347 nm, and the hyperfine splitting frequency (ΔE) of 6S_{1/2} is 9.1926 GHz.

The alkali metal atoms other than the cesium atom also have two ground levels and an excited level constituting the Λ-type three levels in a similar manner. Here, in a sodium atom, the wavelength of the D1 line in vacuum is 589.756 nm, the wavelength of the D2 line in vacuum is 589.158 nm, and the hyperfine splitting frequency (ΔE) of 3S_{1/2} is 1.7716 GHz. Further, in a rubidium (⁸⁵Rb) atom, the wavelength of the D1 line in vacuum is 794.979 nm, the wavelength of the D2 line in vacuum is 780.241 nm, and the hyperfine splitting frequency (ΔE) of 5S_{1/2} is 3.0357 GHz. Further, in a rubidium (⁸⁷Rb) atom, the wavelength of the D1 line in vacuum is 794.979 nm, the wavelength of the D2 line in vacuum is 780.241 nm, and the hyperfine splitting frequency (ΔE) of 5S_{1/2} is 6.8346 GHz.

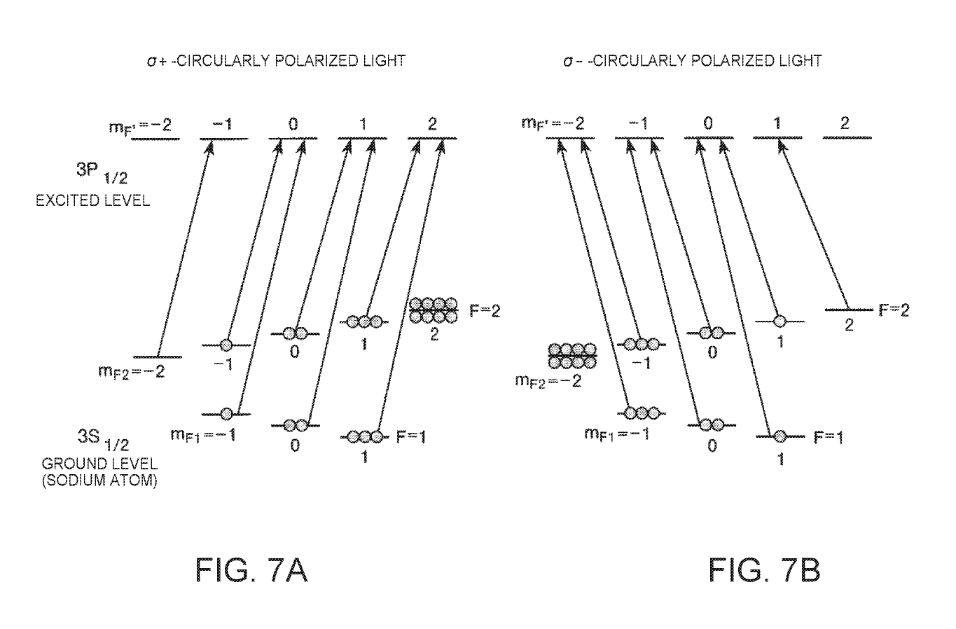

FIGS. 7A and 7B are views showing the distribution of the magnetic quantum number of a sodium atom, and FIG. 7A is a view showing the distribution when the sodium atom was irradiated with a resonance light which is a σ⁺-circularly polarized light, and FIG. 7B is a view showing the distribution when the sodium atom was irradiated with a resonance light which is a σ⁻-circularly polarized light.

For example, as shown in FIGS. 7A and 7B, the sodium atom which is one type of alkali metal atom has the two ground levels and the excited level forming the Λ-type three levels, the first ground level of F=1 in 3S_{1/2} has three magnetic quantum numbers of m_{F1}=−1, 0, and 1, the second ground level of F=2 in 3S_{1/2} has five magnetic quantum numbers of m_{F2}=−2, −1, 0, 1, and 2, and the excited level in 3P_{1/2} has five magnetic quantum numbers of m_{F′}=−2, −1, 0, 1, and 2.

When irradiating the sodium atom in the ground level of F=1 or F=2 with the resonance light pair which is a σ⁺-circularly polarized light, the sodium atom is excited to the excited level under the selection rule that the magnetic quantum number is increased by one as shown in FIG. 7A. At this time, in the sodium atom in the ground level of F=1 or F=2, the distribution changes toward the large magnetic quantum number.

On the other hand, when irradiating the sodium atom in the ground level of F=1 or F=2 with the resonance light pair which is a σ⁻-circularly polarized light, the sodium atom is excited to the excited level under the selection rule that the magnetic quantum number is decreased by one as shown in FIG. 7B. At this time, in the sodium atom in the ground level of F=1 or F=2, the distribution changes to the small magnetic quantum number.

In FIGS. 7A and 7B, the distribution of the magnetic quantum number is shown by taking the sodium atom having a simple structure as an example for the sake of convenience of explanation, however, in other alkali metal atoms, each of the ground levels and the excited level has 2F+1 magnetic quantum numbers (magnetic sublevels), and the distribution of the magnetic quantum numbers changes under the selection rule as described above.

In a case of the cesium atoms, when the cesium atoms are irradiated with only the resonance light pair LL1, the cesium atoms in the first ground level have a small bias in the distribution of the magnetic quantum number, but the number thereof is small, and further, in the cesium atoms in the second ground level, the distribution of the magnetic quantum number is largely biased toward the larger magnetic quantum number. That is, in the atomic oscillator in the related art (for example, the atomic oscillator according to JP-A-2013-181941), all the resonance lights, with which the metal is irradiated, are circularly polarized in one direction. Therefore, it is possible to improve the intensity of the EIT signal as compared with a case where, for example, the resonance light is linearly polarized, however, the effect thereof is not sufficient. This is because since all the resonance lights are circularly polarized in one direction, the distribution is biased either toward the smaller magnetic quantum number of the metal or toward the larger magnetic quantum number of the metal, and therefore, the number of alkali metal atoms having a desired magnetic quantum number which contributes to the EIT decreases.

On the other hand, when the cesium atoms are simultaneously irradiated with both the resonance light pair LL1 and the adjustment light LL2, the cesium atoms in each of the first ground level and the second ground level have a relatively small bias in the distribution of the magnetic quantum number, and the number thereof can be made relatively large. That is, when the cesium atoms are simultaneously irradiated with both the resonance light pair LL1 and the adjustment light LL2, as compared with a case where the cesium atoms are irradiated with only the resonance light pair LL1, while increasing the number of cesium atoms in the respective levels of the first ground level and the second ground level, the distribution of the magnetic quantum number of the cesium atom can be averaged.

Further, when the cesium atoms are simultaneously irradiated with both the resonance light pair LL1 and the adjustment light LL2 (repump on), as compared with a case where the cesium atoms are irradiated with only the resonance light pair LL1 (repump off), the signal intensity of the EIT signal can be increased to about three times while making the full width at half maximum substantially equal.

As described above, in the atomic oscillator 1, by irradiating the alkali metal with the adjustment light LL2 which is circularly polarized in an opposite direction to that of the resonance light pair LL1 in addition to the resonance light pair LL1 which is circularly polarized in the same direction as each other, the bias in the distribution of the magnetic quantum number due to the resonance light pair LL1 can be canceled out or relaxed by the adjustment light LL2, and therefore, the bias in the distribution of the magnetic quantum number of the alkali metal can be reduced. Accordingly, the number of alkali metal atoms having a desired magnetic quantum number which contributes to the EIT is increased, and as a result, an effect of suppressing the decrease in the intensity of the EIT signal is remarkably exhibited using the resonance light pair LL1 which is circularly polarized, and thus, the decrease in the intensity of the EIT signal can be suppressed.

### Detailed Description of Inner Wall Surface and Coating

Next, the inner wall surface 212 and the coating 20 of the atomic cell 2 will be described in detail.

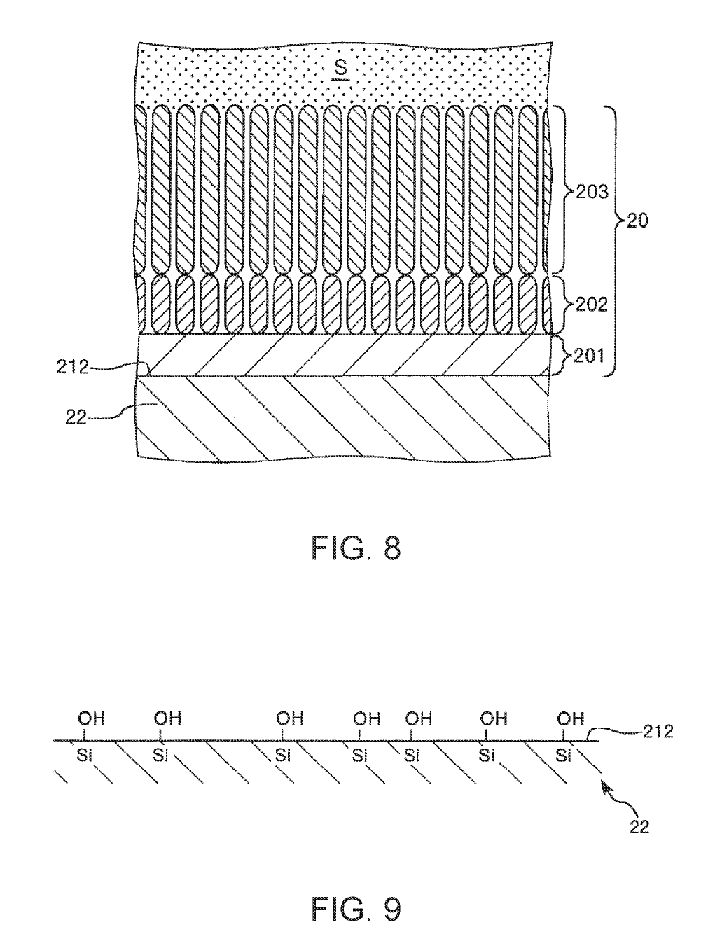

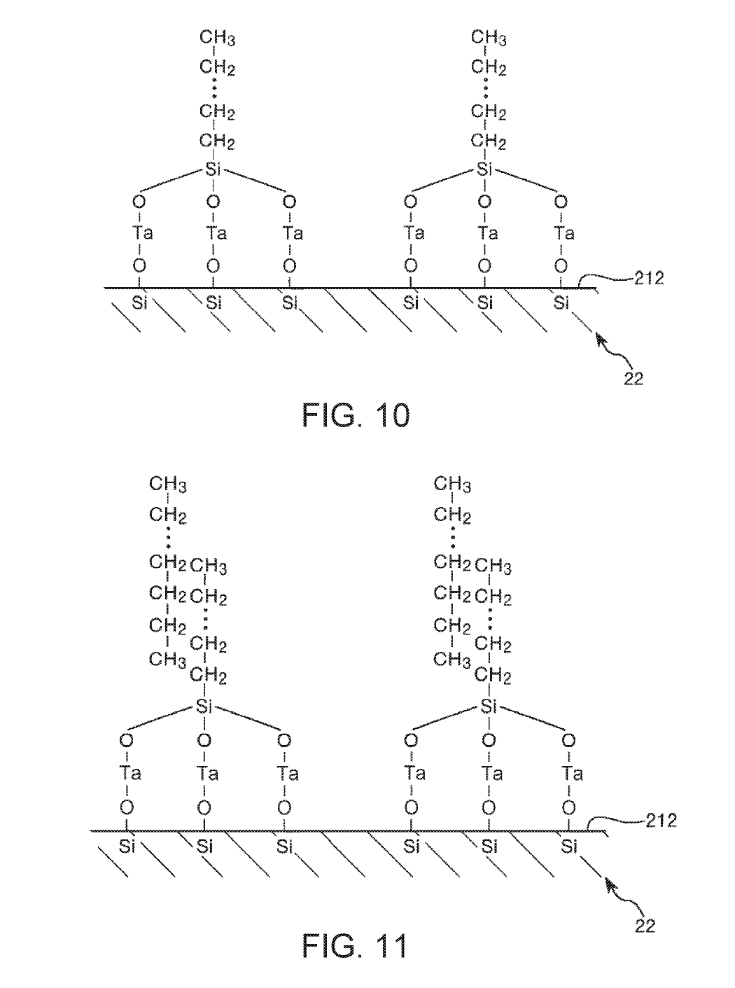

FIG. 8 is a schematic view showing the inner wall surface and the coating of the atomic cell. FIG. 9 is a view for illustrating one example of a polar group of the inner wall surface before forming the coating. FIG. 10 is a view for illustrating one example of the structure of a second layer. FIG. 11 is a view for illustrating one example of the structure of the coating.

As described above, the coating 20 is provided on the inner wall surface 212. As shown in FIG. 8, the coating 20 includes a first layer 201 provided on the inner wall surface 212, a second layer 202 provided on the first layer 201, and a third layer 203 provided on the second layer 202.

### Inner Wall Surface 212

The inner wall surface 212 is formed using a material containing a compound having a polar group. Specifically, as described above, the window parts 22 and 23 are formed using, for example, a glass material such as quartz glass or borosilicate glass. The glass material contains silicon and oxygen, and particularly contains silicon and oxygen as main components. The inner wall surface 212 formed using the glass material is formed using a material containing a compound having a hydroxyl group which is a polar group bound to silicon as shown in FIG. 9.

The window parts 22 and 23 may be formed of a material other than the glass material as described above. Further, the polar group is not limited to a hydroxyl group (—OH) and may be a carboxyl group (—COOH), an amino group (—NH₂), an amide group (—CONH₂), or the like. Further, the polar group may be introduced into the inner wall surface 212 in advance by performing a treatment of introducing the polar group such as an acid treatment, a base treatment, a UV treatment, an ozone treatment, or a plasma treatment. Further, also the body part 21 is formed of the same material as that of the window parts 22 and 23 as described above. The body part 21 may be formed of a different material from that of the window parts 22 and 23.

### First Layer 201

The first layer 201 is formed using a first compound which is an oxide of a metal (metal oxide) having a lower ionization tendency than the alkali metal. Specifically, the first layer 201 is formed by allowing the first compound to undergo a chemical reaction with the polar group (for example, a hydroxyl group) of a material forming the inner wall surface 212.

Specifically, the first compound is preferably a tantalum oxide (TaOx), a zirconium oxide (ZrOx), a hafnium oxide (HfOx), or a titanium oxide (TiOx). For example, the oxygen of the tantalum oxide replaces the hydroxyl group of the material forming the inner wall surface 212 and binds the tantalum of the first compound to the silicon of the material forming the inner wall surface 212 (see FIGS. 9 and 10). Tantalum is a metal having a lower ionization tendency than the alkali metal. Due to this, the tantalum oxide does not undergo or hardly undergoes a substitution reaction with the alkali metal. Therefore, for example, the oxygen which binds tantalum being the metal atom of the tantalum oxide to silicon of the material forming the inner wall surface 212 is not replaced by the alkali metal. Accordingly, the possibility of peeling off of the first layer 201 can be reduced. That can also be said about the zirconium oxide, the hafnium oxide, and the titanium oxide.

Into the first compound, for example, a polar group such as a hydroxyl group (—OH) may be introduced. In this case, for example, the polar group (for example, the hydroxyl group) of the material forming the inner wall surface 212 and the polar group included in the first compound undergo an elimination reaction (dehydration condensation reaction), whereby the first compound and the inner wall surface 212 are bound to each other. Further, a polar group may be introduced into the first compound in advance by performing a treatment of introducing the polar group.

The thickness of such a first layer 201 is, for example, several tens of nanometers.

The first layer 201 may be formed using two or more types of materials cited as examples of the first compound described above. Further, the first layer 201 may be formed using a plurality of first compounds of the same type having different molecular weights.

### Second Layer 202

The second layer 202 is formed using a second compound having a functional group which undergoes an elimination reaction with the first compound. Specifically, the second layer 202 is formed by allowing the functional group of the second compound to undergo a chemical reaction with the first compound. For example, the second layer 202 is formed by allowing the functional group of the second compound to undergo an elimination reaction with the polar group included in the first compound.

Specifically, the second compound is preferably an alkylsilane, an alcohol, or a polyimide. According to this, the orientation of the second layer 202 can be enhanced, and further, the orientation of the below-mentioned third layer 203 can also be enhanced accompanying this. Therefore, the penetration of the alkali metal between the second compound molecules or between the third compound molecules can be suppressed. Due to this, the relaxation of the electron spin state of the alkali metal can be particularly decreased. Further, even if the third layer 203 is melted, since the second layer 202 is oriented, the orientation of the third layer 203 can be restored by cooling only once without performing ripening. The ripening is a heat treatment for orienting the second compound.

Examples of the form of the second compound include a straight chain (linear shape), a coil, a ring, a branched chain, and a net, and among these, a straight chain form is preferred. According to this, the orientation of the second layer 202 can be enhanced. In this case, it is particularly preferred that the functional group which undergoes an elimination reaction is present at a terminal end of the straight chain.

### Alkylsilane

The alkylsilane has a functional group which undergoes an elimination reaction with the first compound and an alkyl chain (alkyl group) which is a nonpolar group (nonpolar unit) connected to the functional group through silicon. The nonpolar group has excellent affinity for the below-mentioned third compound which is nonpolar. Therefore, the adhesion between the second layer 202 and the third layer 203 can be enhanced.

The alkylsilane is preferably octadecyltrimethoxysilane (ODS, CH₃(CH₂)₁₇Si(OCH₃)₃ or octadecyltrichlorosilane (OTS, CH₃(CH₂)₁₇SiCl₃). The chemical formula of ODS is the following formula (1). The chemical formula of OTS is the following formula (2).

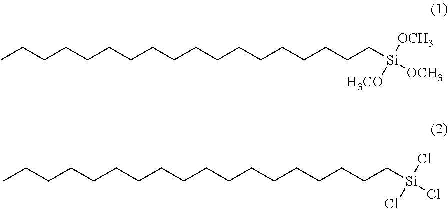 [SMILES: CCCCCCCCCCCCCCCCCC[Si](OC)(OC)OC ; CCCCCCCCCCCCCCCCCC[Si](Cl)(Cl)Cl]

By using OTS or ODS, the elimination reaction thereof with the first compound can be more easily and reliably caused. Specifically, ODS has a methoxy group (—OCH₃) which is a functional group and the methoxy group undergoes an elimination reaction with the first compound. OTS has a chloro group (—Cl) which is a functional group and the chloro group undergoes an elimination reaction with the first compound.

Further, the decomposition temperature of ODS is about 200° C., and the decomposition temperature of OTS is about 200° C. Therefore, by using ODS or OTS, the heat resistance of the second layer 202 can be enhanced.

For example, ODS is applied onto the first layer 201 in a state of being dispersed in a solvent such as cyclohexane, hexane, or chloroform. For example, the methoxy group of ODS is replaced by the oxygen of the first compound which forms the first layer 201, and as shown in FIG. 10, the oxygen of the first compound binds the tantalum of the first compound to the silicon of ODS. Further, for example, in a case where the first compound has a hydroxyl group which is a polar group, when ODS reaches the hydroxyl group, the methoxy group of ODS and the hydrogen of the hydroxyl group of the first compound are eliminated, and the silicon of ODS and the oxygen of the first compound are bound to each other. Accordingly, the second layer 202 is formed. The same applies to OTS.

Further, ODS has a functional group (methoxy group) located at a terminal end and a straight-chain nonpolar group (alkyl chain) connected to the functional group through silicon. Because of having a straight-chain nonpolar group, the steric hindrance is small and the orientation of the second layer 202 can be enhanced. In the example shown in the drawing, the carbon atoms included in the compound derived from ODS extend parallel to the vertical line of the inner wall surface 212. According to this, the second layer 202 has particularly high orientation. The same applies to OTS.

The number of carbon atoms in the alkyl chain included in the alkylsilane is not particularly limited, but is preferably, for example, from 5 to 30, more preferably from 10 to 25.

### Alcohol

The alcohol has a hydroxyl group which is a functional group that undergoes an elimination reaction with the first compound and an alkyl chain (alkyl group) which is a nonpolar group. The nonpolar group has excellent affinity for the below-mentioned third compound which is nonpolar. Therefore, the adhesion between the second layer 202 and the third layer 203 can be enhanced.

Examples of the alcohol include straight-chain alcohols such as decyl alcohol and octadecyl alcohol. By using such a straight-chain alcohol having a hydroxyl group at a terminal end, the second layer 202 has high orientation.

### Polyimide

In a case of using a polyimide, it is preferred to form the second layer 202 by subjecting a layer formed of the polyimide to a rubbing treatment. Further, in a case of using a polyimide, a functional group which undergoes an elimination reaction with the first compound may be introduced. Further, in a case of using a polyimide, a nonpolar group may be introduced. Examples of the nonpolar group include an alkyl group and an aryl group.

The functional group included in the second compound described above may be any group as long as it is a group which undergoes an elimination reaction (including a group which undergoes a dehydration condensation reaction) with the polar group included in the first compound.

The thickness of such a second layer 202 is, for example, several tens of nanometers.

The second layer 202 may be formed using two or more types of materials cited as examples of the second compound described above. Further, the second layer 202 may be formed using a plurality of second compounds of the same type having different molecular weights.

### Third Layer 203

As described above, the third layer 203 is formed using a third compound which is nonpolar. The second compound and the third compound are different compounds.

By providing the third layer 203 formed using the third compound which is nonpolar on the second layer 202, the coating 20 has excellent orientation and high coverage. Due to this, by providing the third layer 203, the inner wall surface 212 can be prevented from being exposed. Therefore, in the atomic cell 2, the alkali metal is highly likely to collide with the third layer 203 without colliding with the inner wall surface 212, and therefore, the effect of the collision on the quantum state of the alkali metal can be made small. That is, by including the third layer 203, the relaxation of the electron spin state (spin polarization) of the alkali metal due to the collision can be decreased. In this manner, the third layer 203 has an excellent non-relaxation property for the alkali metal of the atomic cell 2. If a configuration in which only the second layer 202 is provided is adopted, although the orientation can be enhanced, it is difficult to increase the coverage. Alternatively, if a configuration in which a plurality of second layers 202 are stacked is adopted, although the coverage can be increased, it is difficult to enhance the orientation.

The third compound is preferably an olefin-based polymer. The olefin-based polymer generally has a higher melting point than paraffin. Therefore, by using the third compound which is an olefin-based polymer, the heat resistance of the third layer 203 can be enhanced as compared with a configuration in which paraffin is used in the related art. As a result, the heat resistance of the atomic cell 2 can be enhanced, and therefore, the effect of the collision on the quantum state of the alkali metal can be made small even under a higher temperature (for example, 100° C. or higher) condition.

Specifically, the third compound is preferably polypropylene (PP, (C₃H₆)ₙ), polyethylene (PE, (C₂H₄)ₙ), or polymethylpentene (PMP, (C₆H₁₂)ₙ). In the formulae, n is an integer of 1 or more. The chemical formula of PP is the following formula (3). The chemical formula of PE is the following formula (4). The chemical formula of PMP is the following formula (5). PP, PE, and PMP each have a higher melting point than paraffin. Therefore, the melting point of the third layer 203 can be increased as compared with the paraffin coating in the related art, and thus, the heat resistance of the atomic cell 2 can be enhanced as compared with the related art.

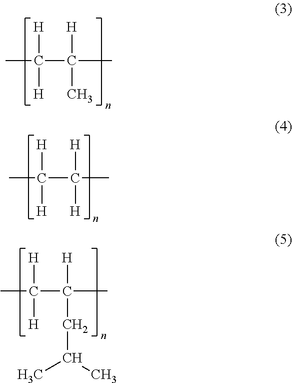

The melting point of PP is, for example, about 170° C. The melting point of PE is, for example, about 120° C. The melting point of PMP is, for example, about 230° C. The number average molecular weight Mn of PP is, for example, about 5000. The weight average molecular weight Mw of PP is, for example, about 12000. The melt index (MI) of PE is, for example, about 2.2 g/10 min (190° C./2.16 kg).

The weight average molecular weight Mw of the olefin-based polymer is not particularly limited, but is preferably, for example, from 5000 to 50000, more preferably from 10000 to 30000.

FIG. 11 is a view showing a state in which when ODS is used as the second compound and straight-chain PP is used as the third compound, PP is physically adsorbed on ODS. PP is nonpolar but has a large molecular weight, and therefore, a strong intermolecular attractive force is generated between PP and the nonpolar group (alkyl group) of ODS. Then, PP is physically adsorbed on the nonpolar group of ODS by the intermolecular attractive force. In this manner, the third layer 203 is formed. The second compound and the third compound may be chemically bound to each other.

Examples of the form of the third compound include a straight chain (linear shape), a coil, a ring, a branched chain, and a net, and among these, a straight chain (including a slightly branched chain) is preferred. According to this, the steric hindrance is small, and therefore, the orientation of the third layer 203 can be further enhanced under the influence of the orientation of the second layer 202 having excellent orientation.

Further, the third compound is preferably subjected to electron-beam crosslinking. By being subjected to electron-beam crosslinking, the third compound can be modified into a net-like structure by crosslinking the third compound molecules. According to this, the heat resistance of the third layer 203 can be enhanced.

The stereoregularity of the third compound is not particularly limited, and for example, polypropylene (PP) may be isotactic polypropylene or syndiotactic polypropylene.

Further, by depositing the third compound a plurality of times, the thickness of the third layer 203 can be adjusted. The thickness of the third layer 203 is, for example, several hundreds of nanometers and is thicker than the thickness of the second layer 202.

The third layer 203 may be formed using two or more types of materials cited as examples of the third compound described above. Further, the third layer 203 may be formed using a plurality of third compounds of the same type having different molecular weights.

The combination of the compounds to be used for forming the coating 20 having such a configuration, that is, the first compound, the second compound, and the third compound is not particularly limited, however, it is particularly preferred that the first compound is a tantalum oxide, the second compound is octadecyltrimethoxysilane (ODS), and the third compound is polypropylene (PP). According to this, the coating 20 has excellent heat resistance, excellent orientation, and high coverage. Therefore, the heat resistance of the atomic cell 2 can be particularly enhanced, and also the relaxation of the electron spin state of the alkali metal can be particularly decreased. Further, the coating 20 is particularly less likely to be peeled off, and therefore has excellent durability. Further, for example, in a case where the second compound is OTS, hydrogen chloride whose handling requires caution is sometimes generated when OTS undergoes an elimination reaction with the inner wall surface 212, however, ODS does not require such caution and can be handled easily. Further, PP has a higher melting point than PE. Therefore, by using ODS as the second compound and PP as the third compound, the atomic cell 2 which is easy to handle and has higher heat resistance can be provided.

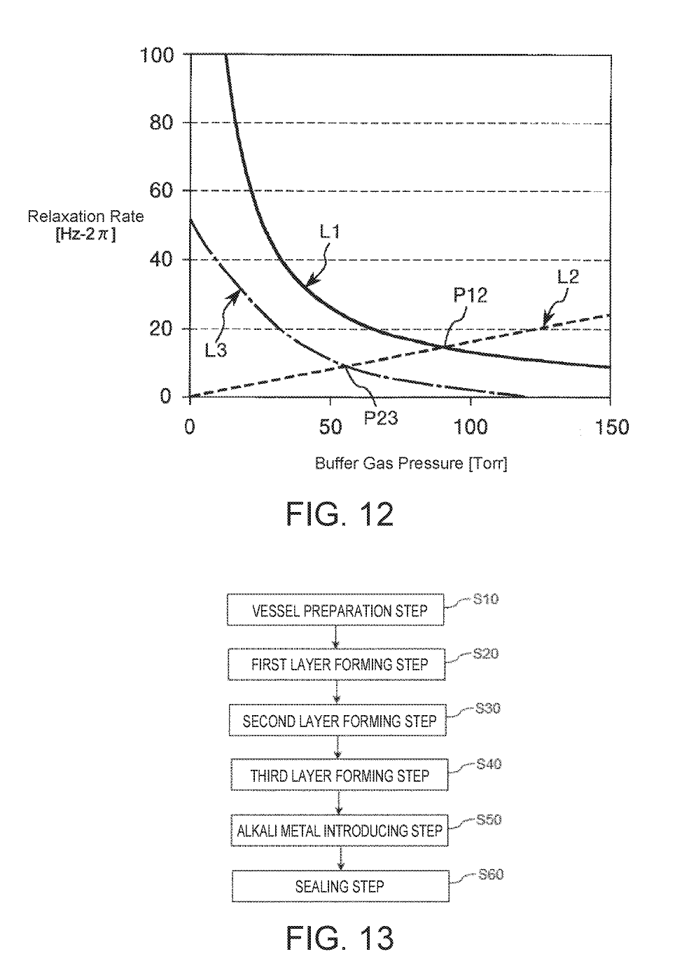

FIG. 12 is a graph showing a relationship between a buffer gas enclosed in the internal space of the atomic cell and a relaxation rate.

A segment L1 shown in FIG. 12 indicates the relaxation rate (the relaxation of the spin polarization of the cesium atom) due to the collision of the cesium atom with the wall part (the inner wall surface 212) when the buffer gas is present in the atomic cell which is not provided with the coating 20. A segment L2 indicates the relaxation rate due to the spin exchange interaction between the cesium atom and the buffer gas. A segment L3 indicates the relaxation rate due to the collision of the cesium atom with the wall part (the surface 205 of the coating 20) when the buffer gas is present in the atomic cell 2 which is provided with the coating 20 (excluding the first layer 201). The relaxation rate is calculated based on the diffusion coefficient of the cesium atom, the size of the internal space S, the reference pressure (760 Torr), etc.

As found by comparison between the segment L1 and the segment L3 shown in FIG. 12, by providing the coating 20, as compared with a case where the coating 20 is not provided, the relaxation rate due to collision with the wall part of the atomic cell 2 can be decreased. The segment L3 indicates the relaxation rate for the coating which does not include the first layer 201, however, even in a case of the coating 20 including the first layer 201, the same tendency was exhibited.

Further, by decreasing the sum of the relaxation rate due to collision with the wall part of the atomic cell 2 and the relaxation rate due to the spin exchange interaction with the buffer gas (the sum of the relaxation rates), the relaxation of the electron spin state of the cesium atom in the atomic cell 2 can be decreased. The relaxation rate at an intersection point P23 between the segment L2 and the segment L3 is smaller than the relaxation rate at an intersection point P12 between the segment L1 and the segment L2. Therefore, in a case where the coating 20 is provided, as compared with a case where the coating 20 is not provided, the sum of the relaxation rates can be decreased. That is, by providing the coating 20, the relaxation of the electron spin state of the cesium atom in the atomic cell 2 can be decreased.

Even when the film thickness, material, or the like of the coating 20 was changed, the same tendency was exhibited. Further, the relaxation due to the spin breaking interaction between the alkali metal atoms also occurred, however, this was sufficiently smaller than the relaxation rate due to collision with the wall part or the relaxation due to the spin exchange interaction with the buffer gas.

Further, by using the atomic cell 2 including the coating 20, the pressure (partial pressure) of the buffer gas can be set to about 20 to 90 (Torr), more preferably about 20 to 70 (Torr). In this manner, by using the atomic cell 2 including the coating 20, while decreasing the relaxation of the electron spin state of the alkali metal in the atomic cell 2, the pressure of the buffer gas can be decreased as compared with the related art.

As described above, the atomic oscillator 1 including the quantum interference device according to the embodiment includes the atomic cell 2 which has the internal space S enclosing the alkali metal (in this embodiment, the cesium atom). Further, the atomic oscillator 1 includes the first light source 31 which emits the resonance light pair that is circularly polarized in the same direction as each other and excites the alkali metal, and the second light source 32 which emits the adjustment light that is circularly polarized in the opposite direction to that of the resonance light pair and excites the atoms of the alkali metal (alkali metal atoms) in the internal space S. Further, the atomic oscillator 1 includes the light receiver 4 which receives the resonance light pair passing through the internal space S. The atomic cell 2 includes the first layer 201 which is provided on the inner wall surface 212 surrounding the internal space S of the atomic cell 2 and contains a compound derived from the first compound that is an oxide of a metal having a lower ionization tendency than the alkali metal, the second layer 202 which is provided on the first layer 201 and contains a compound derived from the second compound having a functional group that undergoes an elimination reaction with the compound derived from the first compound, and the third layer 203 which is provided on the second layer 202 and contains a compound derived from the third compound that is nonpolar.

According to such an atomic oscillator 1, by irradiating the alkali metal (in this embodiment, the cesium atom) with the resonance light which is circularly polarized in the opposite direction to that of the resonance light pair as the adjustment light in addition to the resonance light pair which is circularly polarized in the same direction as each other, the bias in the distribution of the magnetic quantum number due to the resonance light pair can be canceled out or relaxed by the adjustment light, and therefore, the bias in the distribution of the magnetic quantum number of the alkali metal can be reduced. Accordingly, the number of alkali metal atoms having a desired magnetic quantum number which contributes to the EIT is increased, and as a result, an effect of suppressing the decrease in the intensity of the EIT signal can be exhibited using the resonance light pair which is circularly polarized.

Further, by including the second layer 202 and the third layer 203 in the atomic cell 2, both orientation and coverage of the coating 20 can be achieved. Therefore, the relaxation of the electron spin state of the alkali metal due to collision with the inner wall surface 212 can be decreased or suppressed, so that the interaction time between the light LL and the alkali metal can be increased.

Here, if a configuration in which only the resonance light pair which is circularly polarized in the same direction as each other is used is adopted, when the interaction time is increased by providing the coating 20, the bias in the distribution of the magnetic quantum number is increased. Therefore, in the atomic oscillator 1, the adjustment light (the resonance light which is circularly polarized in the opposite direction to that of the resonance light pair) is used in addition to the resonance light pair. Due to this, even if the interaction time is long, the bias in the distribution of the magnetic quantum number can be decreased. Therefore, according to the atomic oscillator 1, by including the atomic cell 2 provided with the coating 20, and also including the second light source 32 which emits the adjustment light together with the first light source 31 which emits the resonance light pair, the relaxation of the electron spin state of the alkali metal is decreased, and the interaction time is increased, whereby the line width of the EIT signal can be decreased, and also the bias in the distribution of the magnetic quantum number due to the increase in the interaction time can be reduced. As a result, the decrease in the intensity of the EIT signal can be suppressed.

Further, the coating 20 includes the first layer 201 between the second layer 202 and the inner wall surface 212. The first layer 201 is formed of the first compound which is an oxide of a metal having a lower ionization tendency than the alkali metal. The first compound does not undergo or hardly undergoes a substitution reaction with the alkali metal. Therefore, the cleavage of a bond between a compound of a material forming the inner wall surface 212 and the first compound due to the alkali metal can be suppressed. Accordingly, the possibility of peeling off of the first layer 201 can be reduced.

In light of the above, according to the atomic oscillator 1, the possibility of peeling off of the coating 20 can be reduced, and also the decrease in the intensity of the EIT signal can be suppressed.

The structure of the compound derived from the first compound contained in the first layer 201 may not be changed from the structure of the first compound. Similarly, the structure of the compound derived from the second compound contained in the second layer 202 may not be changed from the structure of the second compound, and the structure of the compound derived from the third compound contained in the third layer 203 may not be changed from the structure of the third compound.

### 2. Production Method for Atomic Cell

Next, a production method for the atomic cell 2 included in the atomic oscillator 1 according to this embodiment will be described. Hereinbelow, a case where the body part 21 and the window parts 22 and 23 are constituted by a glass will be described as an example.

FIG. 13 is a flowchart illustrating the production method for the atomic cell.

As shown in FIG. 13, the production method for the atomic cell 2 includes [1] a vessel preparation step S10, [2] a first layer forming step S20, [3] a second layer forming step S30, [4] a third layer forming step S40, [5] an alkali metal introducing step S50, and [6] a sealing step S60. Hereinafter, the respective steps will be sequentially described.

### [1] Vessel Preparation Step S10

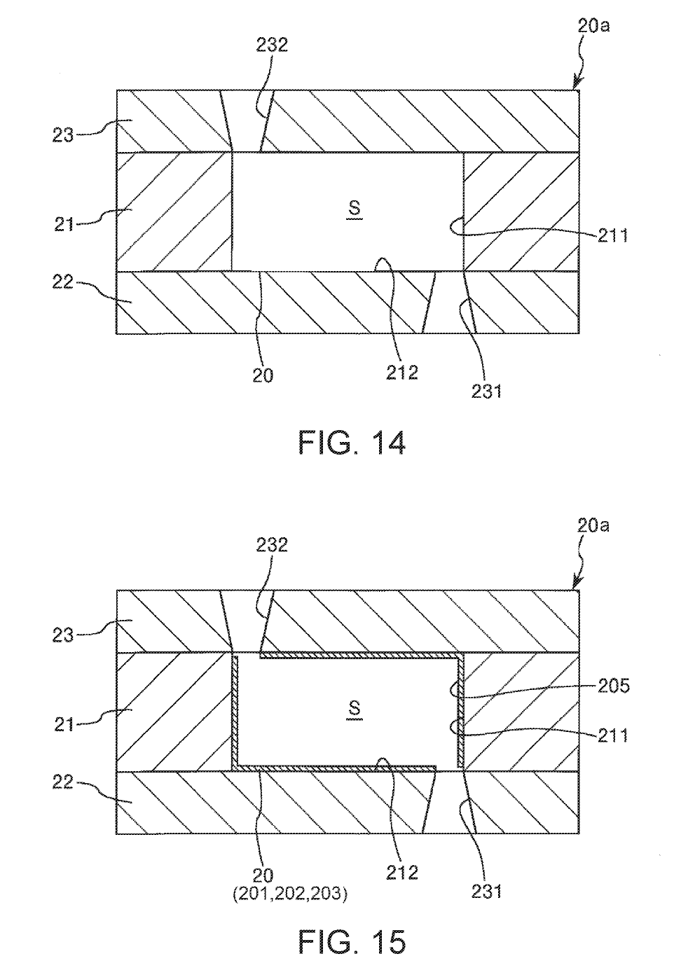

FIG. 14 is a view illustrating the vessel preparation step shown in FIG. 13.

First, as shown in FIG. 14, a vessel 20a is prepared. This vessel 20a is a structure which is in a state before performing the sealing by the sealants 241 and 242, the formation of the coating 20, and the enclosing of the alkali metal in the atomic cell 2, and has the body part 21 and the pair of window parts 22 and 23.

Each of the body part 21 and the window parts 22 and 23 can be formed by processing a substrate (for example, a glass substrate) using an etching technique or a photolithographic technique. Further, as the method for bonding the body part 21 to the window parts 22 and 23, for example, a bonding method using an adhesive, a direct bonding method, or the like is used.

### [2] First Layer Forming Step S20

Subsequently, the first compound is introduced into the internal space S through the through holes 231 and 232, whereby the first layer 201 is formed on the inner wall surface 212.

The first layer 201 is formed by, for example, a CVD method, an atomic layer deposition (ALD) method, a sputtering method, an ion plating method, a sol-gel method, or the like. In a case where the first layer 201 is formed by, for example, a CVD method, the first compound in a gaseous state is deposited on the inner wall surface 212 through the through holes 231 and 232.

### [3] Second Layer Forming Step S30

Subsequently, the second compound is introduced into the internal space S through the through holes 231 and 232, whereby the second layer 202 is formed on the first layer 201.

The second layer 202 is formed by, for example, a coating method, a CVD method, or the like. In a case where the second layer 202 is formed by a coating method, for example, the second compound is dispersed in a given solvent, and the resulting dispersion is applied to the first layer 201 through the through holes 231 and 232, followed by drying. In a case where the second layer 202 is formed by a CVD method, the second compound in a gaseous state is deposited on the first layer 201 through the through hole 231 and 232.

### [4] Third Layer Forming Step S40

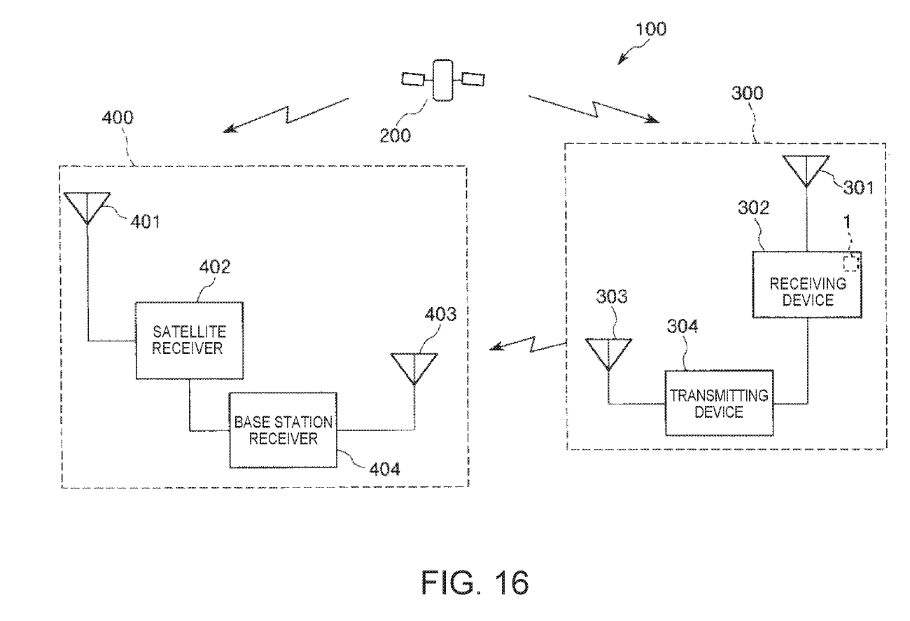

FIG. 15 is a view illustrating the third layer forming step shown in FIG. 13.

Subsequently, the third compound is introduced into the internal space S through the through holes 231 and 232, whereby the third layer 203 is formed on the second layer 202. By doing this, the coating 20 can be obtained (see FIG. 15).

The third layer 203 is formed by, for example, a coating method, a vacuum deposition method, or the like. In a case where the third layer 203 is formed by a coating method, the third compound is dispersed in a given solvent, and the resulting dispersion is applied onto the second layer 202 through the through holes 231 and 232, followed by drying. In a case where the third layer 203 is formed by a vacuum deposition method, the third compound in a gaseous state is deposited on the second layer 202 through the through holes 231 and 232.

Further, by depositing the third compound a plurality of times, the thickness of the third layer 203 can be adjusted.

### [5] Alkali Metal Introducing Step S50

Subsequently, the alkali metal in a gaseous state is introduced (fed) into the internal space S through the through holes 231 and 232. The introduction of the alkali metal is performed under the condition (temperature and pressure) that the coating 20 is not melted.

### [6] Sealing Step S60

Subsequently, the through hole 231 is sealed by the sealant 241, and the through hole 232 is sealed by the sealant 242. For example, by melting a ball-shaped sealant (not shown) with a laser or the like, the sealant 241 or 242 can be formed. By doing this, the internal space S enclosing the alkali metal can be airtightly sealed.

By the above-mentioned steps, the atomic cell 2 can be produced.

### 3. Electronic Apparatus

The atomic oscillator as described above can be incorporated into various types of electronic apparatuses.

Hereinafter, an electronic apparatus according to the embodiments will be described.

FIG. 16 is a view showing a schematic structure in a case where the atomic oscillator according to the embodiment is used in a positioning system utilizing a global positioning system (GPS) satellite as an example of a positioning satellite.

A positioning system 100 shown in FIG. 16 is constituted by a GPS satellite 200, a base station device 300, and a GPS receiving device 400.

The GPS satellite 200 transmits positioning information (GPS signal).

The base station device 300 includes, for example, a receiving device 302 which highly accurately receives a positioning satellite signal from the GPS satellite 200 through an antenna 301 placed at an electronic reference point (GPS continuous observation station) and a transmitting device 304 which transmits the positioning information (phase data or the like) acquired from the positioning satellite signal received by the receiving device 302 through an antenna 303.

The receiving device 302 is an electronic apparatus which includes the above-mentioned atomic oscillator 1 according to the embodiments as a reference frequency oscillation source. Such a receiving device 302 has excellent reliability. Further, the positioning information received by the receiving device 302 is transmitted by the transmitting device 304 in real time.

The GPS receiving device 400 includes a satellite receiver 402 which receives the positioning satellite signal from the GPS satellite 200 through an antenna 401 and a base station receiver 404 which receives positioning information from the base station device 300 through an antenna 403. The GPS receiving device 400 calculates the position of the GPS receiving device 400 using the positioning information and the positioning satellite signal received by the satellite receiver 402.

The receiving device 302 which is the “electronic apparatus” included in the positioning system 100 as described above includes the atomic oscillator 1 which includes the above-mentioned quantum interference device according to the embodiment. Accordingly, by including the quantum interference device capable of reducing the possibility of peeling off of the coating 20 and also capable of suppressing the decrease in the intensity of the EIT signal, the receiving device 302 which is an electronic apparatus having high characteristics can be provided.

The electronic apparatus according to the embodiments are not limited to those described above and can also be applied to, for example, a smartphone, a tablet terminal, a timepiece, a mobile phone, a digital still camera, an inkjet type ejection device (for example, an inkjet printer), a personal computer (a mobile type personal computer and a laptop type personal computer), a television, a video camera, a video tape recorder, a car navigation device, a pager, an electronic organizer (including an electronic organizer with a communication function), an electronic dictionary, an electronic calculator, an electronic gaming machine, a word processor, a workstation, a videophone, a security television monitor, electronic binoculars, a POS terminal, a medical apparatus (for example, an electronic thermometer, a sphygmomanometer, a blood glucose meter, an electrocardiographic device, an ultrasonic diagnostic device, and an electronic endoscope), a fish finder, various types of measurement apparatuses, meters and gauges (for example, meters and gauges for vehicles, aircrafts, and ships), a flight simulator, terrestrial digital broadcasting, a mobile phone base station, a GPS module, and the like.

### 4. Vehicle

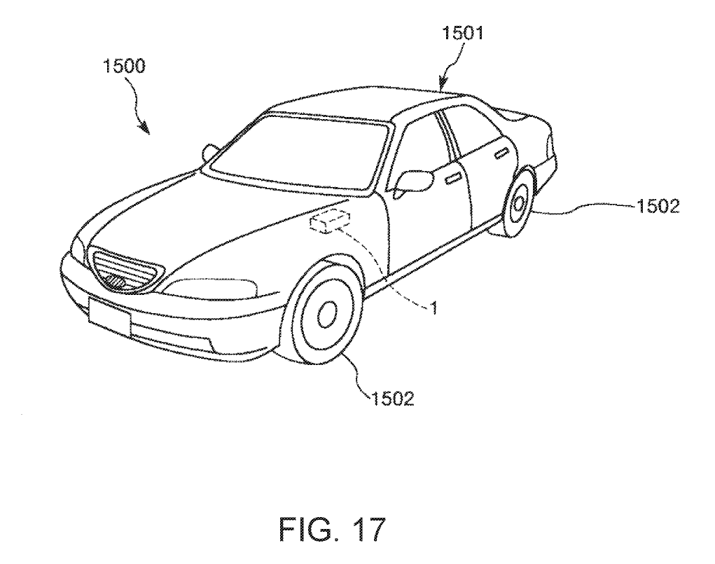

FIG. 17 is a view showing one example of a vehicle according to an embodiment.

In this drawing, a vehicle 1500 includes a car body 1501 and four wheels 1502, and is configured to rotate the wheels 1502 by a power source (engine) (not shown) provided in the car body 1501. The vehicle 1500 incorporates the atomic oscillator 1.

The vehicle 1500 as described above includes the atomic oscillator 1 which includes the above-mentioned quantum interference device according to the embodiments. Accordingly, by including the quantum interference device capable of reducing the possibility of peeling off of the coating 20 and also capable of suppressing the decrease in the intensity of the EIT signal, the vehicle 1500 having high characteristics can be provided.

Hereinabove, the quantum interference device, the atomic oscillator, the electronic apparatus, and the vehicle according to the embodiments have been described based on the embodiments shown in the drawings, however, the invention is not limited thereto.

The configuration of each component of the invention may be replaced with an arbitrary configuration having the same function as in the above-mentioned embodiment, and an arbitrary configuration may also be added. Further, in the invention, arbitrary configurations of the above-mentioned respective embodiments may be appropriately combined with each other.

In the above-mentioned embodiments, the emission direction of the resonance light pair including the first resonance light and the second resonance light and the emission direction of the adjustment light including the third resonance light are not parallel to each other, however, the emission directions of the resonance light pair and the adjustment light may be parallel to each other. Further, in the above-mentioned embodiments, the resonance light pair and the adjustment light are incident from the same side with respect to the atomic cell, however, the resonance light pair and the adjustment light may be incident from different sides with respect to the atomic cell. In this case, the circular polarization directions of the resonance light pair and the adjustment light in the atomic cell may be set to opposite directions. That is, the first resonance light and the second resonance light may both be converted into σ⁺-circularly polarized lights or σ⁻-circularly polarized lights.

What is claimed is:

1. A quantum interference device, comprising:
an atomic cell which has an internal space enclosing an alkali metal;
a first light source which emits a resonance light pair that is circularly polarized in the same direction as each other and excites the alkali metal;
a second light source which emits an adjustment light that is circularly polarized in an opposite direction to that of the resonance light pair and excites the alkali metal; and
a light receiver which receives the resonance light pair passing through the internal space, wherein
the atomic cell includes
a first layer which is provided on an inner wall surface surrounding the internal space of the atomic cell and contains a compound derived from a first compound that is an oxide of a metal having a lower ionization tendency than the alkali metal,
a second layer which is provided on the first layer and contains a compound derived from a second compound having a functional group that undergoes an elimination reaction with the compound derived from the first compound, and
a third layer which is provided on the second layer and contains a compound derived from a third compound that is nonpolar.

2. The quantum interference device according to claim 1, wherein the first compound is a tantalum oxide, a zirconium oxide, a hafnium oxide, or a titanium oxide.

3. The quantum interference device according to claim 1, wherein the second compound is an alkylsilane, an alcohol, or a polyimide.

4. The quantum interference device according to claim 1, wherein the third compound is an olefin-based polymer.

5. The quantum interference device according to claim 4, wherein the third compound is polypropylene, polyethylene, or polymethylpentene.

6. The quantum interference device according to claim 1, wherein
the first compound is a tantalum oxide,
the second compound is octadecyltrimethoxysilane, and
the third compound is polypropylene.

7. An atomic oscillator, comprising a quantum interference device, the quantum interference device comprising:
an atomic cell which has an internal space enclosing an alkali metal;
a first light source which emits a resonance light pair that is circularly polarized in the same direction as each other and excites the alkali metal;
a second light source which emits an adjustment light that is circularly polarized in an opposite direction to that of the resonance light pair and excites the alkali metal; and
a light receiver which receives the resonance light pair passing through the internal space, wherein
the atomic cell includes
a first layer which is provided on an inner wall surface surrounding the internal space of the atomic cell and contains a compound derived from a first compound that is an oxide of a metal having a lower ionization tendency than the alkali metal,
a second layer which is provided on the first layer and contains a compound derived from a second compound having a functional group that undergoes an elimination reaction with the compound derived from the first compound, and
a third layer which is provided on the second layer and contains a compound derived from a third compound that is nonpolar.

8. An electronic apparatus, comprising a quantum interference device, the quantum interference device comprising:
an atomic cell which has an internal space enclosing an alkali metal;
a first light source which emits a resonance light pair that is circularly polarized in the same direction as each other and excites the alkali metal;
a second light source which emits an adjustment light that is circularly polarized in an opposite direction to that of the resonance light pair and excites the alkali metal; and
a light receiver which receives the resonance light pair passing through the internal space, wherein
the atomic cell includes
a first layer which is provided on an inner wall surface surrounding the internal space of the atomic cell and contains a compound derived from a first compound that is an oxide of a metal having a lower ionization tendency than the alkali metal,
a second layer which is provided on the first layer and contains a compound derived from a second compound having a functional group that undergoes an elimination reaction with the compound derived from the first compound, and
a third layer which is provided on the second layer and contains a compound derived from a third compound that is nonpolar.
